(19) United States
(12) Patent Application Publication
(10) Pub. No.: US 2013/0050939 A1
(43) Pub. Date: Feb. 28, 2013

(54) METHODS AND SYSTEM FOR EFFECTIVELY REMOVING HEAT FROM A WIRELESS BASE STATION

(71) Applicants: Jonathan Christopher Burke, Berkeley, CA (US); Dan Picker, San Diego, CA (US)

(72) Inventors: Jonathan Christopher Burke, Berkeley, CA (US); Dan Picker, San Diego, CA (US)

(73) Assignee: PureWave Networks, Inc., Mountain View, CA (US)

(21) Appl. No.: 13/219,692

(22) Filed: Aug. 28, 2011

(51) Int. Cl. H05K 7/20

(52) U.S. Cl. 361/692

(57) ABSTRACT

Various embodiments of systems and methods are presented for effectively removing heat from electrical and electrical-mechanical devices which include relatively high-power Radio-Frequency (RF) components. Improved structure enhances the shielding of components from unwanted and potentially damaging over-heating. Improved structure also enhances the effectiveness by which heat is thermally dissipated by air convection.

### BACKGROUND

In electrical and electrical-mechanical devices which include relatively high-power Radio Frequency (RF) components, the operation of such RF components can generate a significant amount of heat, which is potentially detrimental to both the RF components and to other components in the devices. Mechanical designs of such devices operate imperfectly in the dissipation of such heat.

### BRIEF SUMMARY

One embodiment is a wireless Base Station (BS) system designed to effectively remove heat from high-power Radio-Frequency (RF) components belonging to said system. Such system may include a first mechanical enclosure designed to environmentally seal a first set of electrical components, and a second mechanical enclosure designed to environmentally seal a second set of electrical components including at least one high-power RF component, in which the second mechanical enclosure is mechanically attached to the first mechanical enclosure such that an air-pathway is formed between the first sealed mechanical enclosure and the second sealed mechanical enclosure. In such embodiment, the air-pathway convectively removes heat generated by the high-power RF components, in which air not sealed inside the two mechanical enclosures enters the air-pathway from a first location outside the wireless BS system, the air then absorbs heat from the second mechanical enclosure heated by the at the high-power RF components, and the heated air then exits the air-pathway from a second location outside the wireless BS system.

One embodiment is a method for effectively removing heat from high-power Radio-Frequency (RF) components belonging to a wireless Base Station (BS). In one particular form of such embodiment, a first set of electrical components are placed and operated inside a first sealed environment of a first mechanical enclosure belonging to the wireless BS. In addition, a second set of electrical components are placed and operated inside a second sealed environment of a second mechanical enclosure belonging to the wireless BS, wherein the second set of electrical components comprises at least one high-power RF component, and the second mechanical enclosure attach to the first mechanical enclosure via at least one contact area. Air from outside the wireless BS is allowed to enter the BS from a first location, into an air-pathway formed between the two attached sealed mechanical enclosures. The air absorbs heat from the second mechanical enclosure heated by the at least one high-power RF component, as the air rises inside the air-pathway. The heated air then exit the air-pathway from a second location, thereby removing heat away from the at least one high-power RF component and the wireless BS.

One embodiment is a method for effectively shielding digital electrical components from heat generated by high-power Radio-Frequency (RF) components belonging to a wireless Base Station (BS). In one particular form of such embodiment, digital electrical components are placed and operated inside a first sealed environment of a first mechanical enclosure belonging to the wireless BS. In addition, at least one high-power RF component is placed and operated inside a second sealed environment of a second mechanical enclosure belonging to the wireless BS, wherein the second mechanical enclosure attach to the first mechanical enclosure via at least one contact area. Then an air-pathway is formed between the two attached sealed mechanical enclosures to shield the first set of electrical components from heat generated by the at least one high-power RF component.

### BRIEF DESCRIPTION OF THE DRAWINGS

Embodiments of the present invention are herein described, by way of example only, with reference to the accompanying drawings. With specific reference now to the drawings, it is stressed that the particulars shown are by way of example and for purposes of illustrative discussion of embodiments of the present invention only, and are presented in order to provide what is believed to be the most useful and readily understood description of the principles and conceptual aspects of embodiments of the present invention. In this regard, no attempt is made to show structural details of embodiments in more detail than is necessary for a fundamental understanding of the invention. In the drawings:

FIG. 1A illustrates one embodiment of components comprising a system, seen from an external view of the system;

FIG. 1B illustrates one embodiment of components comprising a system, seen from a different external view of the system;

FIG. 1C illustrates one embodiment of components comprising a system, showing a cross-section of a system after two enclosures have been placed in contact with one another;

FIG. 2 illustrates one embodiment of the components of a system, seen from an external view of the system, in which the directional flow of air is also illustrated;

FIGS. 3A and 3B illustrate one embodiment of components comprising a system, showing two enclosures before they have been placed in contact with one another, in which FIG. 3A illustrates a first enclosure and FIG. 3B illustrates a second enclosure;

FIGS. 3C and 3D illustrate one embodiment of components comprising a system, showing a different position of two enclosures before they have been placed in contact with one another, in which FIG. 3D illustrates a first enclosure and FIG. 3C illustrates a second enclosure;

FIG. 4 illustrates one embodiment of the elements of a method in which heat is effectively removed from high-power Radio Frequency (RF) components belonging to a wireless Base Station (BS); and

FIG. 5 illustrates one embodiment of the elements of a method in which digital electrical components are effectively shielded from heat generated by high-power Radio-Frequency (RF) components belonging to a wireless Base Station.

### DETAILED DESCRIPTION

Various embodiments of systems and methods are presented for effectively removing heat from electrical and electrical-mechanical devices which include relatively high-power Radio-Frequency (RF) components. Improved structure enhances the shielding of components from unwanted and potentially damaging over-heating. Improved structure also enhances the effectiveness by which heat is thermally dissipated by air convection.

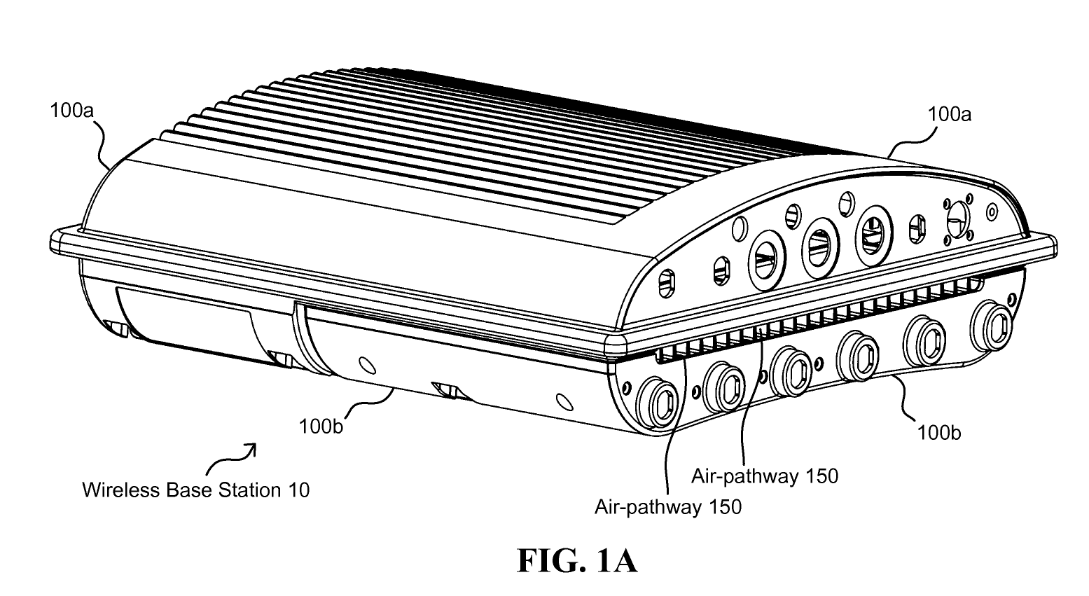

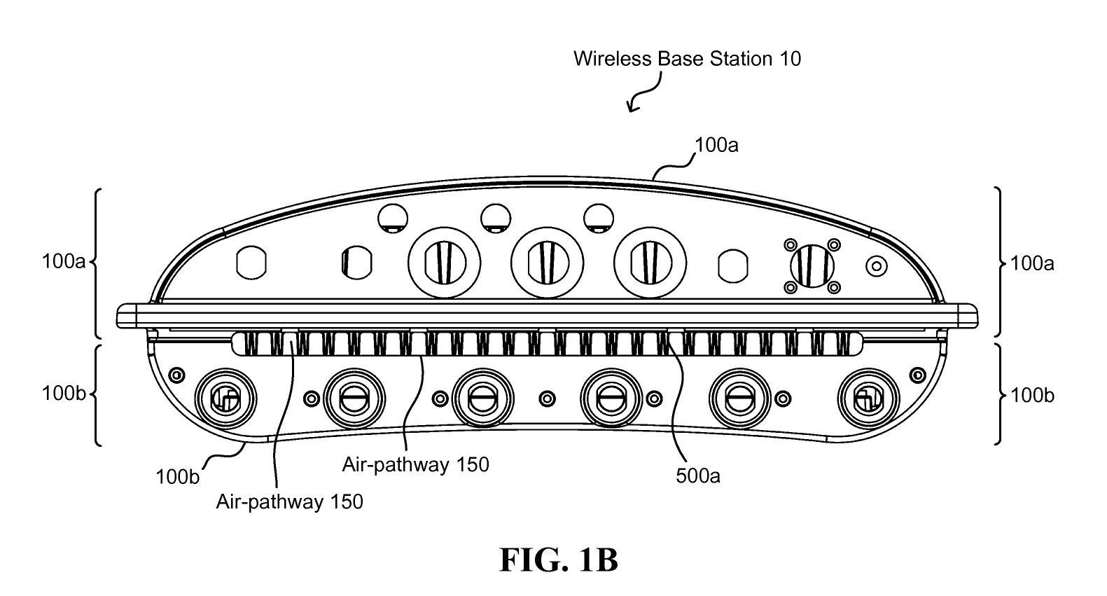

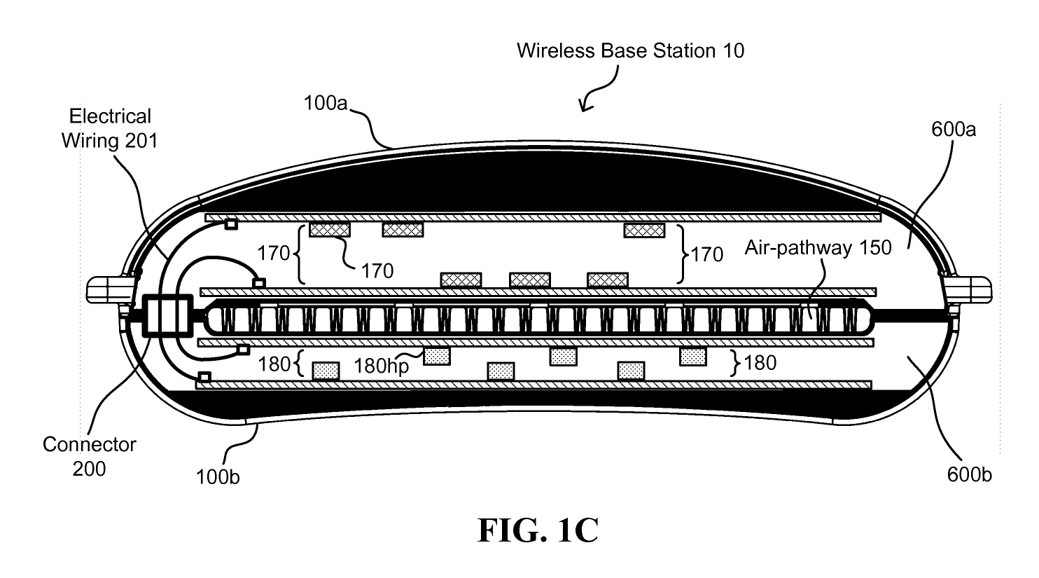

FIG. 1A illustrates one embodiment of components in a system. In FIG. 1A there is a wireless Base Station (BS) 10, including two mechanical enclosures, 100a and 100b. Element 150 depicts an air-pathway that extends through the wireless BS 10. In FIG. 1A, air pathway 150 is effectively an open space that runs through the wireless BS 10, but the open space is divided by a series of fins that also run through the wireless BS 10. It will be understood that this particular showing of air-pathway 150 is not the only possible option, and other formations of air-pathway 150 are possible, provided that air-pathway 150, however it appears, runs substantially the entire length of wireless BS 10.

FIG. 1B illustrates one embodiment of components in a system. FIG. 1B is a view of the top of wireless BS 10, including two mechanical enclosures 100a and 100b. In addition, there is an air-pathway 150 between 100a and 100b. Finally, there is a set of radiating fins 500a protruding into the air-pathway 150. These radiating fins 500a increase the contact area between the second mechanical enclosure 100b and the air-pathway 150, thereby improving heat transfer from the second mechanical enclosure 100b to the air flowing through the air-pathway 150.

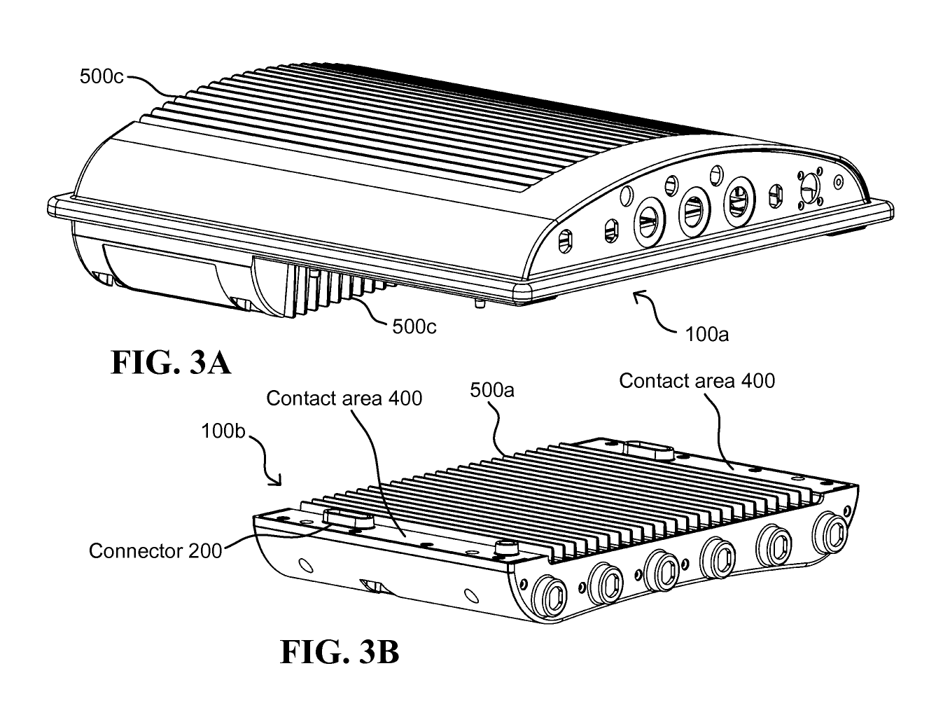

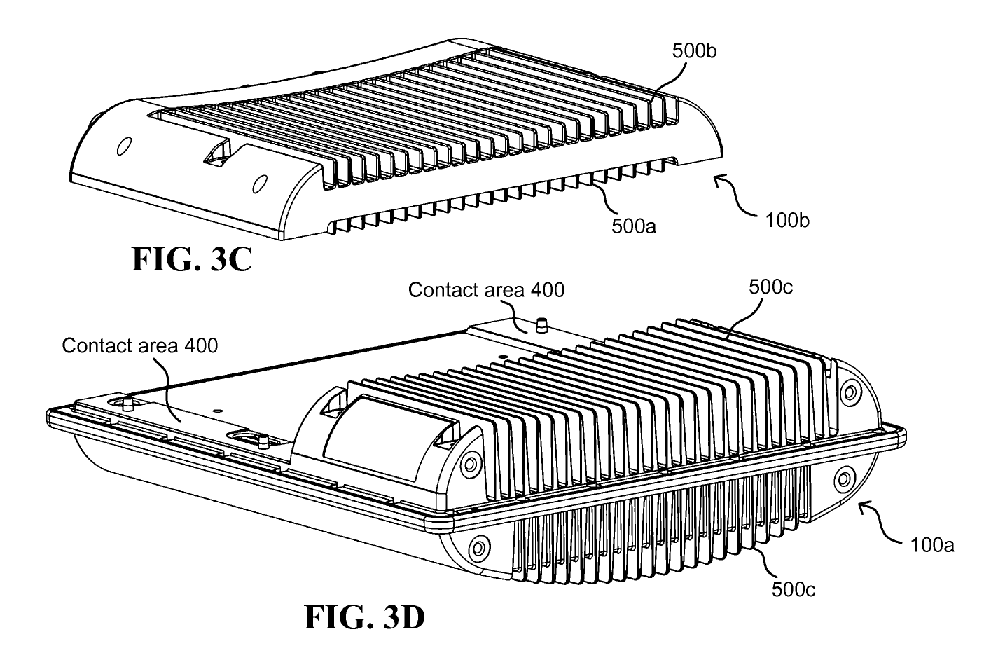

FIG. 1C illustrates one embodiment of components in a system. FIG. 1C is a cross-section view of the wireless BS 10, including two mechanical enclosures 100a and 100b. In addition, there is an air-pathway 150 between 100a and 100b. There is a first sealed environment 600a within the first mechanical enclosure 100a belonging to the wireless BS 10, and a second sealed environment 600b within the second mechanical enclosure 100b belonging to the wireless BS 10. Within the first sealed environment 600a, there is a first set of electrical components 170, which may be RF components, analog components, or digital components, but which do not include any high-power RF components. In the second sealed environment 600b, there is a second set of electrical components 180, which may be RF components, analog components, or digital components, but which in any case include at least one high-power RF component 180hp. The mechanical enclosures 100a and 100b are attached by a contact area 400. (Contact area 400 appears in FIG. 3B.) Contact area 400 includes at least one connector 200, through which electrical wiring 201 connects at least some of the first set of electrical components 170 with at least some of the second set of electrical components 180 & 180hp, thereby allowing the wireless BS 10 to operate as a complete wireless electrical system.

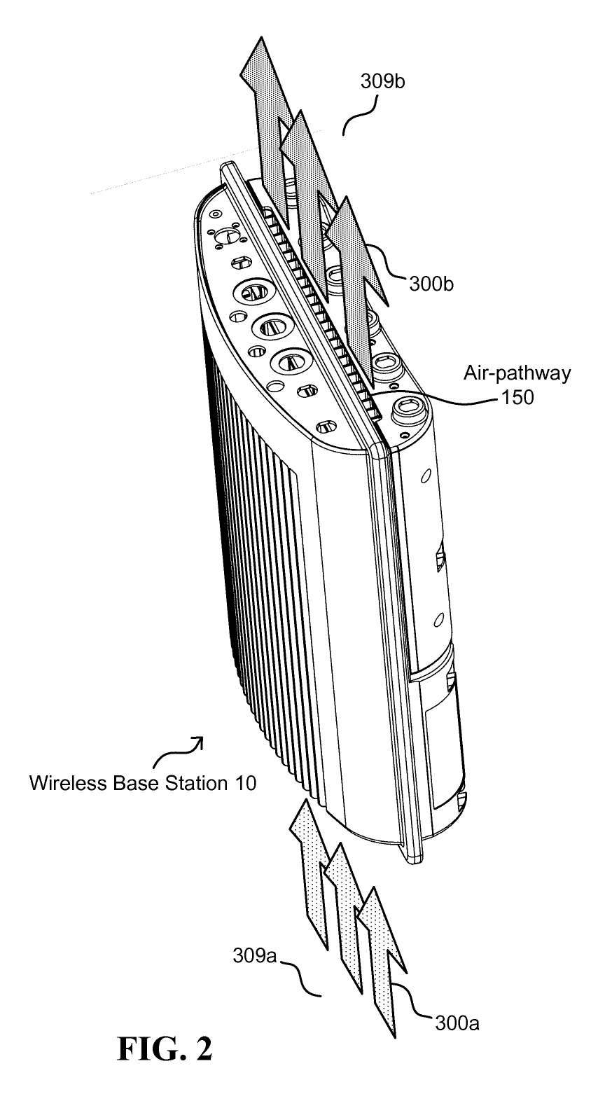

FIG. 2 illustrates one embodiment of components in a system. In FIG. 2, air 300a located at a location outside 309a of the wireless BS 10, enters the air-pathway 150, travels the length of wireless BS 10, and exits as heated air 300b to a location outside 309b of the wireless BS 10.

FIGS. 3A and 3B illustrate one embodiment of components in a system, in which FIG. 3A illustrates first enclosure 100a of wireless Base Station 10, and FIG. 3B is a second enclosure 100b of wireless Base Station (BS) 10. Element 400 is a contact area between 100a and 100b. Contact area 400 includes a connector 200 through which there are electrical connections between various components in the wireless BS 10. A set of internal radiating fins 500a protruding into air-pathway 150 guide air through wireless BS 10. External fins 500c guide air on the outside of wireless BS 10.

FIGS. 3C and 3D illustrate one embodiment of components in a system. They present an alternative view of the embodiment illustrated in FIGS. 3A and 3B. First enclosure 100a appears in FIG. 3D, and second enclosure 100b appears in FIG. 3C. Contact area 400 illustrates an area of contact between 100a and 100b. 500a is a set of internal radiating fins that protrude into air-pathway 150, and that guide air through wireless BS 10. External fins 500b and 500c guide air on the outside of wireless BS 10.

One embodiment of mechanical enclosures 100a and 100b is a clamshell type design. Any other type of design is also possible, as long as the two components 100a and 100b each remain environmentally sealed. Non-limiting examples, such as flat designs or circular designs, would also be possible.

Mechanical enclosures 100a and 100b may be each sealed in any manner that insures liquid-tightness. One embodiment uses gaskets to create a seal. Such caskets may be what is known in the art as “compressed gaskets”, but compression is only one possible embodiment. Non-limiting examples of possible gasket materials to create a seal include constant seating stress gaskets, double-jacketed gaskets, Kammprofile gaskets, spiral-wound gaskets, solid material gaskets, and sheet gaskets. Other non-limiting examples of possible seals include vacuum flanges, vacuum gaskets, and adhesive sealants.

In various embodiments of the seal of each of 100a and 100b, it is possible to use breathable material, which might be, for example, Gore-Tex®, eVent, and c_change membrane. Breathability may help equalize pressure inside and outside the points of seal. Breathability is not required, however, but may be used in various embodiments. Any material, fabric or metal or other, breathable or not breathable, may be used, as long as such material can created an environmental seal for each of 100a and 100b.

In one embodiment, there is a wireless Base Station (BS) 10 system operative to effectively remove heat from high-power Radio-Frequency (RF) components 180hp belonging to said system, including a first mechanical enclosure 100a operative to environmentally seal a first set of electrical components 170, a second mechanical enclosure 100b operative to environmentally seal a second set of electrical components including at least one high-power RF component 180hp, in which the second mechanical enclosure 100b is mechanically attached to the first mechanical enclosure 100a such that an air-pathway 150 is formed between the first sealed mechanical enclosure 100a and the second sealed mechanical enclosure 100b. Air-pathway 150 is operative to convectively remove heat generated by the at least one high-power RF component 180hp, as air 300a not sealed inside the two mechanical enclosures 100a & 100b enters the air-pathway from a first location 309a outside the wireless BS 10 system, the air then absorbs heat from the second mechanical enclosure 100b heated by the at least one high-power RF component 180hp, and the heated air 300b then exits the air-pathway from a second location 309b outside the wireless BS 10 system.

In one alternative embodiment of the embodiment just described, the second mechanical enclosure 100b includes a first set of heat radiating fins 500a protruding into air pathway 150, in which such set of heat radiating fins 500a operate to increase the contact area between the second mechanical enclosure 100b and the air-pathway 150, thereby improving heat flow through the wireless BS 10 system. In this alternative embodiment, it is possible, but not required, that the second mechanical enclosure 100b includes a second set of heat radiating fins 500b, which operate to conduct heat from the second mechanical enclosure 100b to free air surrounding the wireless BS 10, and wherein the first mechanical enclosure 100a includes an additional set of heat generating fins 500c which operate to conduct heat from the first mechanical enclosure 100a to free air surrounding the wireless BS 10. If there are two sets of heat radiating fins, it is possible, in one embodiment, that the first set of heat radiating fins 500a with air-pathway 150 and the second set of heat radiating fins 500b, operate to remove heat from the wireless BS 10 at a rate equal to or even greater than the rate of heat removal achieved by larger systems which do not have a first set of heat radiating fins 500a.

In another alternative embodiment of the embodiment described above, the air-pathway 150 is operative to shield the first set of electrical components 170 from heat generated by the at least one high-powered RF component 180hp. This alternative embodiment includes a number of refining options, such as:

Option I: The alternative embodiment just described, in which the wireless Base Station 10 system is situated such that the location from which air 309a from which air enters the BS 10, is physically lower than the location at which air 308a exits the BS 10. This positioning of the system creates a chimney effect as air first enters 300a, then exits 300b, via the air-pathway 150.

Option II: The alternative embodiment just described, in which the air-pathway 150 convectively removes heat generated by the first set of electrical components 170, as air 300a not sealed inside the two mechanical enclosures 100a & 100b enters the air-pathway 150 from the first location 309a outside the wireless BS 10 system, the air then absorbs heat from the first mechanical enclosure 100a heated by the first set of electrical components 170, and the heated air 300b then exits the air-pathway 150 from the second location 309b outside the wireless BS 10 system.

Option III: The alternative just described, in which the first set of electrical components 170 is capable of operating at a first maximum ambient temperature, the second set of electrical components 180 & 180hp are capable of operating at a second maximum ambient temperature that is higher than the first maximum ambient temperature, heat generated by the first set of electrical components 170 results in a first ambient temperature that is equal to or less than the first maximum ambient temperature, heat generated by the second set of electrical components 180 & 180hp results in a second ambient temperature that is equal to or less than the second maximum ambient temperature but higher than the first maximum ambient temperature, and an ambient temperature difference between the second ambient temperature and the first ambient temperature is maintained by the air-pathway 150 acting as a thermal insulator between the first mechanical enclosure 100a and the second mechanical enclosure 100b. In this option, it is also possible, but not required, that a sheet of thermally insulating material be placed inside air-pathway 150 to further shield the first set of electrical components 170 from heat generated by the at least one high-power RF component 180hp.

Option IV: The alternative just described, in which the first set of electrical components 170 includes digital electrical components, and the air-pathway 150 shields such digital electrical components from heat generated by the at least one high-power RF component 180hp, wherein the at least one high-power RF component 180hp is more temperature resistant than the digital electrical components. In this option, it is possible, but required, that the at least one high-power RF component 180hp includes at least one RF Power Amplifier, and that such at least one RF Power Amplifier dissipates more electrical power than the digital electrical components. Further, if the at least one high-power RF component 180hp includes at least one RF Power Amplifier, it is possible, but required, that the at least one high-power RF component 180hp includes a plurality of RF Power Amplifiers, and that said plurality of RF Power Amplifiers, with or without additional components, drive a plurality of antennas, wherein some or all of such antennas may extend from the second mechanical enclosure 100b.

Option V: The alternative just described, in which the air-pathway 150 reduces substantially the conduct area 400 through which the two mechanical enclosures 100a & 100b attach, thereby substantially reducing heat flow between the two mechanical enclosures 100a & 100b. In this option, it is possible, but not required, that the contact area 400 is located substantially away from the at least one high-power RF component 180hp, thereby further reducing heat flow between the two mechanical enclosures 100a & 100b. Alternatively to or in addition to placement of contact area 400 substantially away from the at least one high-power RF component 180hp, the contact area 400 may include at least one connector 200 through which electrical wiring 201 connects at least part of a first set of electrical components 170 with at least part of a second set of electrical components 180 & 180hp, thereby allowing the wireless BS 10 to function as an integrated wireless electrical system. If an embodiment includes a connector 200 with electrical wiring 201, it is possible, but not required, that the connection 200 operate to preserve the environmental seal of the first mechanical enclosure 100a and the second mechanical enclosure 100b.

It will be understood that various features of these options I, II, III, IV, and V, may be combined to create many other alternative embodiments.

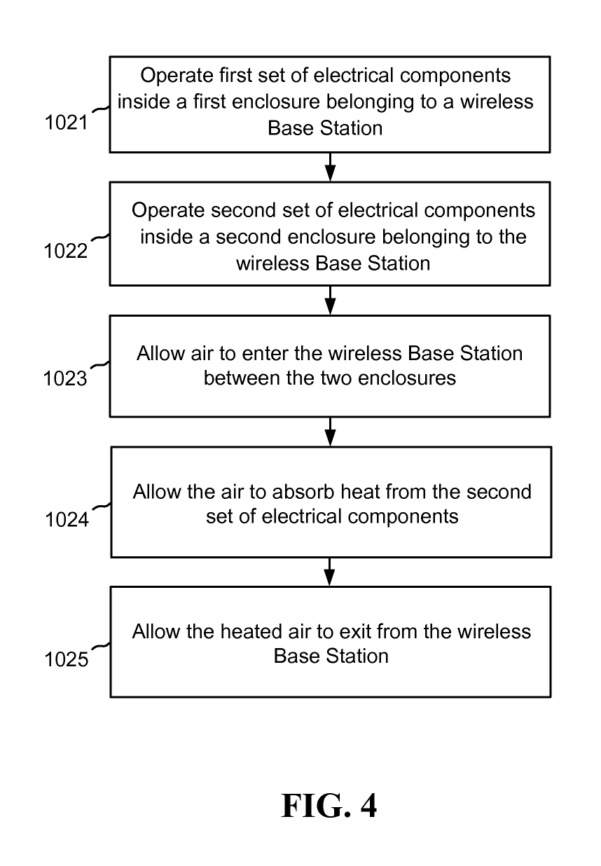

FIG. 4 is a flow diagram illustrating one method for effectively removing heat from high-power Radio-Frequency (RF) components 180hp belonging to a wireless Base Station (BS) 10. In step 1021, operating a first set of electrical components 170 inside a sealed environment 600a of a first mechanical enclosure 100a belonging to a wireless Base Station 10. In step 1022, operating a second set of electrical components 180 & 180hp inside a second sealed environment 600b of a second mechanical enclosure 100b of a wireless Base Station 10. Air enters the wireless BS 10 from outside the BS 309a. In step 1023, the air moves 300a from the outside 309a into the air-pathway 150 in the BS 10. In step 1024, the air absorbs heat from the second mechanical enclosure 100b, wherein second mechanical enclosure 100b, has been heated by the at least one high-power RF component 180hp. The heated air rises in the in the air-pathway 150 in the BS 10. In step 1025, the heated air exits 300b from the wireless BS 10, into a second location 309b, thereby removing heat from the at least one high-power RF component 180hp of the wireless BS 10. In one possible implementation of the method just described, the air-pathway 150 shields the first set of electrical components 170 from heat generated by the high-power RF components 180hp.

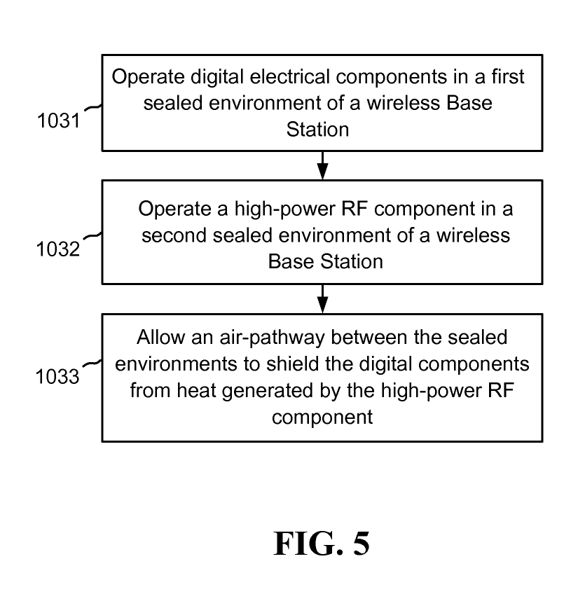

FIG. 5 is a flow diagram illustrating one method for effectively shielding electrical components from heat generated by high-power Radio-Frequency (RF) components 180hp belonging to a wireless Base Stations (BS) 10. In step 1031, operating digital components 170 inside a sealed environment 600a of a first mechanical enclosure 100a belonging to a wireless BS 10. In step 1032, operating at least one high-power RF component 180hp in a second sealed environment 600b of a second mechanical enclosure 100b belonging to a wireless BS 10, wherein the second mechanical enclosure 100b is attached to the first mechanical enclosure 100a via at least one contact area 400. In step 1033, an air-pathway 150 has been formed between the two closed mechanical enclosures 100a & 100b. In one possible implementation of the method just described, air from outside 300a the wireless BS 10 enters from a first location 309a into the air-pathway 150, the air absorbs heat from the second mechanical enclosure 100b heated by the high-power Radio-Frequency (RF) components 180hp, the heated air rises inside the air-pathway 150, and the heated air exists the air-pathway 150 into a second location 309b, thereby removing heat from the at least one high-power RF component 180hp and the wireless BS 10.

In this description, numerous specific details are set forth. However, the embodiments of the invention may be practiced without some of these specific details. In other instances, well-known hardware, software, materials, structures and techniques have not been shown in detail in order not to obscure the understanding of this description. In this description, references to “one embodiment” mean that the feature being referred to may be included in at least one embodiment of the invention. Moreover, separate references to “one embodiment” or “some embodiments” in this description do not necessarily refer to the same embodiment. Illustrated embodiments are not mutually exclusive, unless so stated and except as will be readily apparent to those of ordinary skill in the art. Thus, the invention may include any variety of combinations and/or integrations of the features of the embodiments described herein. Although some embodiments may depict serial operations, the embodiments may perform certain operations in parallel and/or in different orders from those depicted. Moreover, the use of repeated reference numerals and/or letters in the text and/or drawings is for the purpose of simplicity and clarity and does not in itself dictate a relationship between the various embodiments and/or configurations discussed. The embodiments are not limited in their applications to the details of the order or sequence of steps of operation of methods, or to details of implementation of devices, set in the description, drawings, or examples. Moreover, individual blocks illustrated in the figures may be functional in nature and do not necessarily correspond to discrete hardware elements. While the methods disclosed herein have been described and shown with reference to particular steps performed in a particular order, it is understood that these steps may be combined, sub-divided, or reordered to form an equivalent method without departing from the teachings of the embodiments. Accordingly, unless specifically indicated herein, the order and grouping of the steps is not a limitation of the embodiments. Furthermore, methods and mechanisms of the embodiments will sometimes be described in singular form for clarity. However, some embodiments may include multiple iterations of a method or multiple instantiations of a mechanism unless noted otherwise. For example, when an interface is disclosed in an embodiment, the scope of the embodiment is intended to cover also the use of multiple interfaces. Certain features of the embodiments, which may have been, for clarity, described in the context of separate embodiments, may also be provided in various combinations in a single embodiment. Conversely, various features of the embodiments, which may have been, for brevity, described in the context of a single embodiment, may also be provided separately or in any suitable sub-combination. Embodiments described in conjunction with specific examples are presented by way of example, and not limitation. Moreover, it is evident that many alternatives, modifications and variations will be apparent to those skilled in the art. It is to be understood that other embodiments may be utilized and structural changes may be made without departing from the scope of the embodiments. Accordingly, it is intended to embrace all such alternatives, modifications and variations that fall within the spirit and scope of the appended claims and their equivalents.

What is claimed is:

1. A wireless Base Station (BS) system operative to effectively remove heat from high-power Radio-Frequency (RF) components belonging to said system, comprising:
a first mechanical enclosure operative to environmentally seal a first set of electrical components; and
a second mechanical enclosure operative to environmentally seal a second set of electrical components comprising at least one high-power RF component, the second mechanical enclosure mechanically attach to the first mechanical enclosure such that an air-pathway is formed between the first sealed mechanical enclosure and the second sealed mechanical enclosure;
wherein the air-pathway is operative to convectively remove heat generated by the at least one high-power RF component, as air not sealed inside the two mechanical enclosures enters the air-pathway from a first location outside the wireless BS system, the air then absorbs heat from the second mechanical enclosure heated by the at least one high-power RF component, and the heated air then exits the air-pathway from a second location outside the wireless BS system.

2. The system of claim 1, wherein the air-pathway operative to shield the first set of electrical component from heat generated by the at least one high-power RF component.

3. The system of claim 2, wherein the first location has lower elevation than the second location, thereby creating a “chimney effect” as the air enters and exits the air-pathway.

4. The system of claim 2, wherein the air-pathway is operative to convectively remove heat generated by the first set of electrical component, as air not sealed inside the two mechanical enclosures enters the air-pathway from the first location outside the wireless BS system, the air then absorbs heat from the first mechanical enclosure heated by the first set of electrical components, and the heated air then exits the air-pathway from the second location outside the wireless BS system.

5. The system of claim 2, wherein:
the first set of electrical components are capable of operating at a first maximum ambient temperature;
the second set of electrical components are capable of operating at a second maximum ambient temperature that is higher than the first maximum ambient temperature;
heat generated by the first set of electrical components results in a first ambient temperature that is equal to at most the first maximum ambient temperature;
heat generated by the second set of electrical components results in a second ambient temperature that is equal to at most the second maximum ambient temperature, but is higher than the first maximum ambient temperature; and
an ambient temperature difference between the second ambient temperature and the first ambient temperature is maintained by the air-pathway acting as a thermal insulator between the first mechanical enclosure and the second mechanical enclosure.

6. The system of claim 5, wherein a thermal insulator sheet inside the air-pathway is used to further shield the first set of electrical components from heat generated by the at least one high-power RF component

7. The system of claim 2, wherein the first set of electrical components comprises digital electrical components, and the air-pathway shields the digital electrical components from heat generated by the at least one high-power RF component, which is more temperature resistant than the digital electrical components.

8. The system of claim 7, wherein the at least one high-power RF component comprises at least one RF Power Amplifier, and the at least one RF Power Amplifier dissipates more electrical power than the digital electrical components.

9. The system of claim 7, wherein the at least one high-power RF component comprises a plurality of RF Power Amplifiers, driving a plurality of antennas extending from the second mechanical enclosure.

10. The system of claim 2, wherein the air-pathway operative to substantially reduce a contact area through which the two mechanical enclosures attach, thereby substantially reducing heat flow between the two mechanical enclosures.

11. The system of claim 10, wherein the contact area is located substantially away from the at least one high-power RF component, thereby further reducing heat flow between the two mechanical enclosures.

12. The system of claim 10, wherein the contact area comprises at least one connector through which electrical wiring connect at least some of the first set of electrical components with at least some of the second set of electrical components, thereby allowing the wireless BS to operate as an integrated wireless electrical system.

13. The system of claim 12, wherein the at least one connector is operative to preserve environmental seal of the first mechanical enclosure and the second mechanical enclosure.

14. The system of claim 1, wherein the second mechanical enclosure comprises a first set of heat radiating fins protruding into the air-pathway, and the first set of heat radiating fins operative to increase contact area between the second mechanical enclosure and the air-pathway, thereby improving heat flow.

15. The system of claim 14, wherein the second mechanical enclosure comprises a second set of heat radiating fins operative to conduct heat from the second mechanical enclosure to free air surrounding the wireless BS, and the first mechanical enclosure comprises an additional set of heat radiating fins operative to conduct heat from the first mechanical enclosure to free air surrounding the wireless BS.

16. The system of claim 15, wherein the first set of heat radiating fins together with the air-pathway together with the second set of heat radiating fins together with the additional set of heat radiating fins are operative to remove heat at a rate comparable to heat removed by larger systems not having the first set of heat radiating fins and the air-pathway.

17. A method for effectively removing heat from high-power Radio-Frequency (RF) components belonging to a wireless Base Station (BS), comprising:
operating a first set of electrical components inside a first sealed environment of a first mechanical enclosure belonging to the wireless BS;
operating a second set of electrical components inside a second sealed environment of a second mechanical enclosure belonging to the wireless BS, wherein the second set of electrical components comprises at least one high-power RF component, and the second mechanical enclosure attach to the first mechanical enclosure via at least one contact area;
letting air from outside the wireless BS enter from a first location into an air-pathway formed between the two attached sealed mechanical enclosures;
letting the air absorb heat from the second mechanical enclosure heated by the at least one high-power RF component, as the air rises inside the air-pathway; and
letting the heated air exit the air-pathway into a second location, thereby removing heat from the at least one high-power RF component and the wireless BS.

18. The method of claim 17, further comprising letting the air-pathway shield the first set of electrical components from heat generated by the at least one high-power RF component.

19. A method for effectively shielding digital electrical components from heat generated by high-power Radio-Frequency (RF) components belonging to a wireless Base Station (BS), comprising:
operating digital electrical components inside a first sealed environment of a first mechanical enclosure belonging to the wireless BS;
operating at least one high-power RF component inside a second sealed environment of a second mechanical enclosure belonging to the wireless BS, wherein the second mechanical enclosure attach to the first mechanical enclosure via at least one contact area; and
letting an air-pathway formed between the two attached mechanical enclosures shield the first set of electrical components from heat generated by the at least one high-power RF component.

20. The method of claim 19, further comprising:
letting air from outside the wireless BS enter from a first location into the air-pathway;
letting the air absorb heat from the second mechanical enclosure heated by the at least one high-power RF component, as the air rises inside the air-pathway; and
letting the heated air exit the air-pathway into a second location, thereby removing heat from the at least one high-power RF component and the wireless BS.
